(19) United States
(12) Patent Application Publication
(10) Pub. No.: US 2026/0155194 A1
(43) Pub. Date: Jun. 4, 2026

(54) SEMICONDUCTOR MEMORY DEVICE

(71) Applicant: SK hynix Inc., Gyeonggi-do (KR)

(72) Inventor: Min Cheol KIM, Gyeonggi-do (KR)

(21) Appl. No.: 19/209,705

(22) Filed: May 15, 2025

(30) Foreign Application Priority Data
Dec. 2, 2024 (KR) 10-2024-0176732

(51) Int. Cl. G11C 29/12; G11C 29/38; G11C 29/40; G11C 29/46

(52) U.S. Cl. CPC G11C 29/1201; G11C 29/38; G11C 29/46; G11C 2029/1202; G11C 2029/4002

(57) ABSTRACT

A semiconductor memory device for storing data is disclosed. The semiconductor memory device includes at least one cell region including a plurality of memory cells connected between a plurality of wordlines and a plurality of bitlines, wherein a precharge operation is performed on the plurality of memory cells during a precharge operation period; at least one source-voltage supply circuit configured to supply a second voltage having a lower level than a first voltage based on a second voltage activation signal; at least one wordline driving circuit configured to operate based on the second voltage, and drive the plurality of wordlines according to a main wordline driving signal; and a defect detection circuit configured to detect a level change of the second voltage during the precharge operation period, and output a defect flag signal indicating whether the at least one wordline driving circuit is defective.

### CROSS-REFERENCE TO RELATED APPLICATION

This patent application claims the priority and benefits of Korean patent application No. 10-2024-0176732, filed on Dec. 2, 2024, which is incorporated herein by reference in its entirety.

### TECHNICAL FIELD

Embodiments of the present disclosure generally relate to a semiconductor memory device capable of storing data therein.

### BACKGROUND

A dynamic memory device such as a dynamic random access memory (DRAM) can store data in the form of charges. The memory device may include memory cells for storing data, wordlines for driving the memory cells, and bitlines for inputting and outputting data to and from the memory cells.

To perform an operation of accessing one or more memory cells in the memory device, at least one of a plurality of wordlines should be selected and activated. To this end, the memory device may include a wordline driving circuit for controlling the plurality of wordlines. However, a short-circuit defect may occur in the wordline driving circuit due to complications encountered in a fabrication process of the memory device. Such a defect may increase standby power of the memory device and may cause malfunction of the memory device.

### SUMMARY

Various embodiments of the present disclosure relate to a semiconductor memory device that detects a level of a source voltage supplied to a wordline driving circuit during a precharge operation and thus detects a defect of the wordline driving circuit.

In accordance with an embodiment of the present disclosure, a semiconductor memory device may include at least one cell region including a plurality of memory cells connected between a plurality of wordlines and a plurality of bitlines, wherein a precharge operation is performed on the plurality of memory cells during a precharge operation period; at least one source-voltage supply circuit configured to supply a second voltage having a lower level than a pumping voltage according to a second voltage activation signal; at least one wordline driving circuit configured to operate based on the second voltage, and drive the plurality of wordlines according to a main wordline driving signal; and a defect detection circuit configured to detect a level change of the second voltage during the precharge operation period, and output a defect flag signal indicating whether the at least one wordline driving circuit is defective.

It is to be understood that both the foregoing general description and the following detailed description of the present disclosure are illustrative and descriptive and are intended to provide further description of the embodiments as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a schematic diagram illustrating a semiconductor memory device based on some embodiments of the present disclosure.

FIG. 2 is a circuit diagram illustrating a wordline driving circuit and a source-voltage supply circuit shown in FIG. 1 based on some embodiments of the present disclosure.

FIG. 3 is a circuit diagram illustrating voltage paths of a main wordline driver, a sub-wordline driver, and a source-voltage supply circuit shown in FIG. 1 during an active operation based on some embodiments of the present disclosure.

FIG. 4 is a circuit diagram illustrating voltage paths of a main wordline driver, a sub-wordline driver, and a source-voltage supply circuit shown in FIG. 1 during a precharge operation based on some embodiments of the present disclosure.

FIG. 5 is a timing diagram illustrating operations of the semiconductor memory device shown in FIG. 1 based on some embodiments of the present disclosure.

FIG. 6 is a circuit diagram illustrating a defect detection circuit shown in FIG. 1 based on some embodiments of the present disclosure.

FIG. 7 is a circuit diagram illustrating another embodiment of the defect detection circuit shown in FIG. 1 based on the present disclosure.

FIG. 8 is a block diagram illustrating a memory system including the semiconductor memory device shown in FIG. 1 based on some embodiments of the present disclosure.

### DETAILED DESCRIPTION

The embodiments and examples of the present disclosure provide a semiconductor memory device capable of storing data therein, which may be used in configurations to substantially address one or more technical or engineering issues and to mitigate limitations or disadvantages encountered in some other semiconductor memory devices. Some embodiments of the present disclosure relate to a semiconductor memory device that detects a level of a source voltage supplied to a wordline driving circuit during a precharge operation and thus detects a defect of the wordline driving circuit. In recognition of the issues above, the semiconductor memory device based on some embodiments of the present disclosure may determine the presence or absence of a defect for each mat, so that the semiconductor memory device may reduce the area of a defect detection circuit and may also reduce a test time required for determining the presence or absence of the defect.

Reference will now be made in detail to some embodiments of the present disclosure, examples of which are illustrated in the accompanying drawings. Wherever possible, the same reference numbers will be used throughout the drawings to refer to the same or like parts. While this disclosure is susceptible to various modifications and alternative forms, specific embodiments thereof are shown by way of example in the drawings. However, this disclosure should not be construed as being limited to the embodiments set forth herein.

Hereinafter, various embodiments of the present disclosure will be described with reference to the accompanying drawings. However, it should be understood that the present disclosure is not limited to specific embodiments, but includes various modifications, equivalents and/or alternatives of the embodiments. The embodiments of the present disclosure may provide a variety of advantageous effects capable of being directly or indirectly recognized.

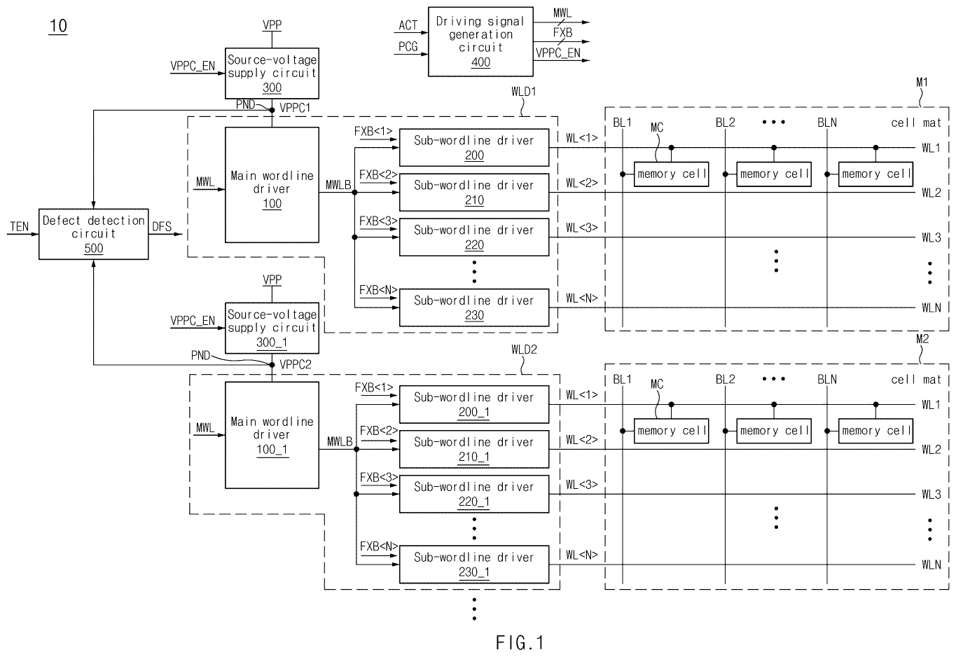

FIG. 1 is a schematic diagram illustrating a semiconductor memory device 10 based on some embodiments of the present disclosure.

Referring to FIG. 1, the semiconductor memory device 10 may include a plurality of cell mats (i.e., a plurality of cell regions) M1, M2, a plurality of wordline driving circuits WLD1 and WLD2, a plurality of source-voltage supply circuits 300 and 300_1, a driving signal generation circuit 400, and a defect detection circuit 500.

Each of the plurality of cell mats M1, M2 may include a plurality of memory cells MC arranged in a matrix structure including rows and columns between a plurality of wordlines WL<1:N> and a plurality of bitlines BL1 to BLN. The semiconductor memory device 10 may perform a basic operation of selecting at least one of the plurality of memory cells MC, storing external data in the selected memory cell MC, or outputting data stored in the selected memory cell MC to the outside. In this case, the term “cell mat” may mean a set of multiple memory cells MC and may mean a unit of valid memory cells in which data is written to and read from the memory cells MC.

Each wordline WL may be connected to the memory cells MC. One memory cell MC may be connected between a wordline WL and a bitline BL that cross each other. The memory cell MC may be designed such that a specific wordline is activated by a row address and a specific bitline BL is activated by a column address. Then, the read or write operation of data may be performed in a memory cell MC connected between the activated wordline WL and the activated bitline BL.

A plurality of wordline driving circuits WLD1 and WLD2 may drive the plurality of wordlines WL<1:N> based on a main wordline driving signal MWL. In the embodiment of FIG. 1, only two wordline driving circuits WLD1 and WLD2 from among the plurality of wordline driving circuits are illustrated. The wordline driving circuit WLD1 may drive the plurality of wordlines WL<1:N> corresponding to a cell mat M1, and the wordline driving circuit WLD2 may drive the plurality of wordlines WL<1:N> corresponding to a cell mat M2.

The wordline driving circuit WLD1 may include a main wordline driver 100 and a plurality of sub-wordline drivers 200 to 230. The main wordline driver 100 may generate a main wordline signal MWLB based on a main wordline driving signal MWL. The plurality of sub-wordline drivers 200 to 230 may drive the plurality of wordlines WL<1:N> based on a main wordline signal MWLB and a sub-wordline driving signal FXB.

The wordline driving circuit WLD2 may include a main wordline driver 100_1 and a plurality of sub-wordline drivers 200_1 to 230_1. The main wordline driver 100_1 may generate a main wordline signal MWLB based on the main wordline driving signal MWL. The plurality of sub-wordline drivers 200_1 to 230_1 may drive the plurality of wordlines WL<1:N> based on the main wordline signal MWLB and the sub-wordline drive signal FXB.

The main wordline drivers 100 and 100_1 may receive a cell mat selection signal and an address for selecting the cell mats M1 and M2, but a detailed description thereof will be omitted in FIG. 1. In addition, the number of main wordline drivers and the number of sub-wordline drivers may vary depending on the number of bits in the row address.

The main wordline drivers 100, 100_1 may receive a source voltage from the source-voltage supply circuits 300, 300_1 through a power node PND.

The plurality of source-voltage supply circuits 300 and 300_1 may supply the source voltage to the main wordline drivers 100 and 100_1 through the power node PND based on a driving voltage enable signal (i.e., a second voltage enable signal) VPPC_EN. Here, the source voltage may be a pumping voltage (i.e., a boosted voltage) VPP indicating a first voltage, or a driving voltage VPPC indicating a second voltage. The pumping voltage VPP may have a higher voltage level than the power-supply voltage VDD. The driving voltage VPPC may be a lower voltage level than the pumping voltage VPP.

For example, the source-voltage supply circuits 300 and 300_1 may supply a pumping voltage VPP to the power node PND during the active operation period, may supply the driving voltage VPPC to the power node PND during the precharge operation period. The driving voltage to be supplied from the source-voltage supply circuit 300 to the main wordline driver block 100 will hereinafter be defined as VPPC1 for convenience of description, and the driving voltage to be supplied from the source-voltage supply circuit 300_1 to the main wordline driver block 100_1 will hereinafter be defined as VPPC2 for convenience of description.

The source-voltage supply circuit 300 may supply the driving voltage VPPC1 that is matched to the wordline driving circuit WLD1 and the cell mat M1. In addition, the source-voltage supply circuit 300_1 may supply the driving voltage VPPC2 that is matched to the wordline driving circuit WLD2 and the cell mat M2. That is, the source-voltage supply circuits 300 and 300_1 may provide the driving voltages VPPC1 and VPPC2 to the plurality of cell mats M1 and M2 independently from each other. In more detail, the source-voltage supply circuit 300 may provide the driving voltage VPPC1 to the cell mat M1, and the source-voltage supply circuit 300-1 may provide the driving voltage VPPC2 to the cell mat M2. For example, the number of the source-voltage supply circuits 300 and 300_1 may correspond to the number of wordline driving circuits WLD1 and WLD2 and the number of cell mats M1 and M2.

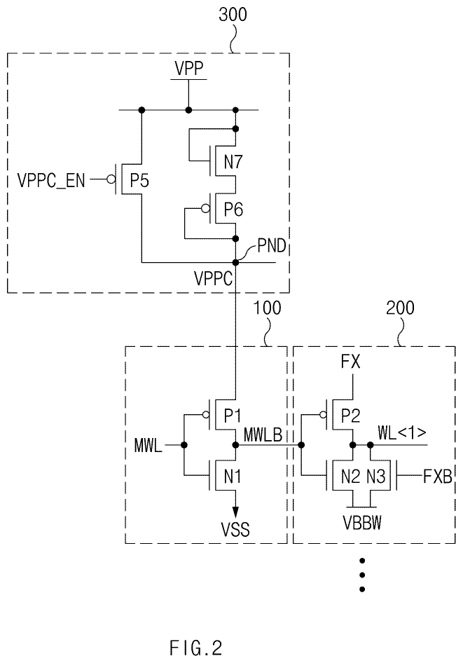

Detailed configurations and operations of the main wordline drivers 100 and 100_1, the plurality of sub-wordline drivers 200 to 230 and 200_1 to 230_1, and the plurality of source-voltage supply circuits 300 and 300_1 will be described later with reference to FIGS. 2 to 6.

The driving signal generation circuit 400 may receive an active signal ACT and a precharge signal PCG, and may generate a main wordline driving signal MWL, a sub-wordline driving signal FXB, and a driving voltage activation signal VPPC_EN.

The active signal ACT may be a signal activated during the read operation of data and the write operation of data, and the precharge signal PCG may be a signal activated during the precharge operation of the memory cell MC. For example, the active signal ACT and the precharge signal PCG may be signals generated from a command decoder not shown.

The main wordline drive signal MWL may be a signal for selecting the main wordline, and the sub-wordline drive signal FXB may be a signal for selecting the wordline WL.

In addition, the driving voltage enable signal VPPC_EN may be a signal for selecting the source voltage (i.e., the pumping voltage VPP or the driving voltage VPPC) to be supplied from the source-voltage supply circuit 300 to the power node PND. The driving voltage enable signal VPPC_EN may be a signal to be controlled by the active signal ACT. For example, the driving voltage enable signal VPPC_EN may be a signal that transitions to a logic low level when the active signal ACT is activated and transitions to a logic high level when the precharge signal PCG is activated.

The defect detection circuit 500 may detect whether a short-circuit defect occurs in the wordline driving circuits WLD1 and WLD2 by detecting a change in the level of the driving voltages VPPC1 and VPPC2 supplied from the source-voltage supply circuits 300 and 300_1 to the main wordline drivers 100 and 100_1. For example, the defect detection circuit 500 may detect a change in the level of the driving voltages VPPC1 and VPPC2 when the test enable signal TEN is activated in the precharge operation period, and may output a defect flag signal DFS indicating whether a defect exists. For example, the test enable signal TEN may be a signal that is activated when the precharge signal PCG is activated in the precharge operation period.

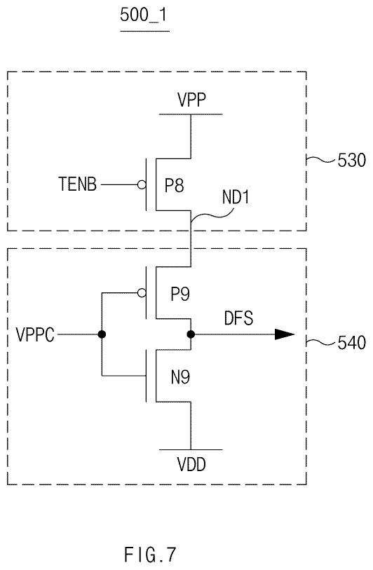

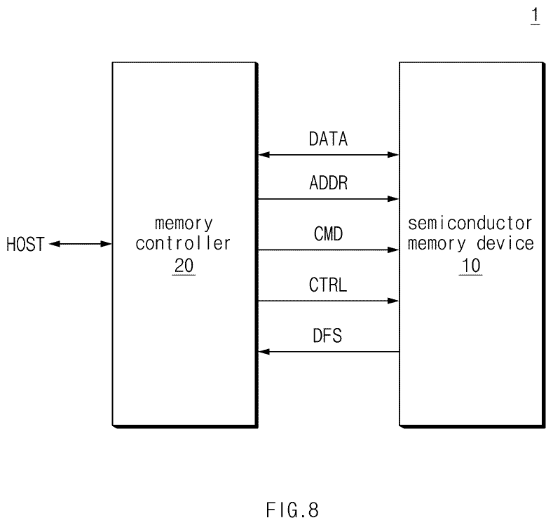

The detailed configuration and operation of the above-described defect detection circuit 500 will be described later in more detail with reference to FIGS. 7 and 8.

FIG. 2 is a circuit diagram illustrating the wordline driving circuit and the source-voltage supply circuit shown in FIG. 1 based on some embodiments of the present disclosure.

In the embodiment of FIG. 2, only one sub-wordline driver 200 from among the plurality of sub-wordline drivers 200 to 230 is illustrated. Referring to FIG. 2, the main wordline driver 100 may include transistors P1 and N1. The transistor P1 may be a PMOS transistor, and the transistor N1 may be an NMOS transistor.

The transistors P1 and N1 may be connected in series between the power node PND and the ground voltage VSS input terminal. Each of the transistors P1 and N1 may receive the main wordline driving signal MWL through a common gate terminal. The transistors P1 and N1 may output the main wordline signal MWLB through a common drain terminal.

The sub-wordline driver 200 may include transistors P2, N2 and N3. The transistor P2 may be a PMOS transistor, and each of the transistors N2 and N3 may be an NMOS transistor.

The transistors P2 and N2 may be connected in series between a sub-wordline drive signal FX input terminal and a negative wordline voltage VBBW input terminal. Here, the negative wordline voltage VBBW may be a ground voltage VSS level or may have a lower voltage level than the ground voltage VSS. The transistors P2 and N2 may receive the main wordline signal MWLB through a common gate terminal thereof. The transistors P2 and N2 may have a common drain terminal connected to the wordline WL<1>.

The transistor N3 may be connected between the wordline WL<1> and the negative wordline voltage VBBW input terminal, and may receive the sub-wordline driving signal FXB through a gate terminal thereof. Here, the sub-wordline driving signal FXB may be an inverted signal, also called an inversion signal, of the sub-wordline driving signal FX.

The source-voltage supply circuit 300 may include transistors P5, P6, N7. The transistors P5 and P6 may be PMOS transistors, and the transistor N7 may be an NMOS transistor.

The transistor P5 may be connected between the pumping voltage VPP input terminal and the power node PND, and may receive the driving voltage activation signal VPPC_EN through a gate terminal thereof. The transistor P5 may operate as a switch element that is turned on or off based on the driving voltage activation signal VPPC_EN. The transistor P5 may set the power node PND to the pumping voltage VPP level when the driving voltage activation signal VPPC_EN is at a logic low level.

The transistors N7 and P6 may be connected in series between the pumping voltage VPP input terminal and the power node PND. The transistor N7 may include gate and drain terminals commonly connected to the pumping voltage VPP input terminal. The transistor P6 may include gate and drain terminals commonly connected to the power node PND. The transistor N7 and the transistor P6 may operate as diode elements to clamp the voltage level of the driving voltage VPPC.

That is, the source-voltage supply circuit 300 may maintain the voltage level of the driving voltage VPPC so that the voltage level of the driving voltage VPPC does not fall below a voltage level obtained by subtracting a preset voltage from the pumping voltage VPP based on the driving voltage enable signal VPPC_EN. For example, in the test mode, the driving voltage VPPC may have a lower voltage level than the pumping voltage VPP by a threshold voltage (i.e., a threshold voltage of the transistor N7+a threshold voltage of the transistor P6) of the transistors N7 and P6.

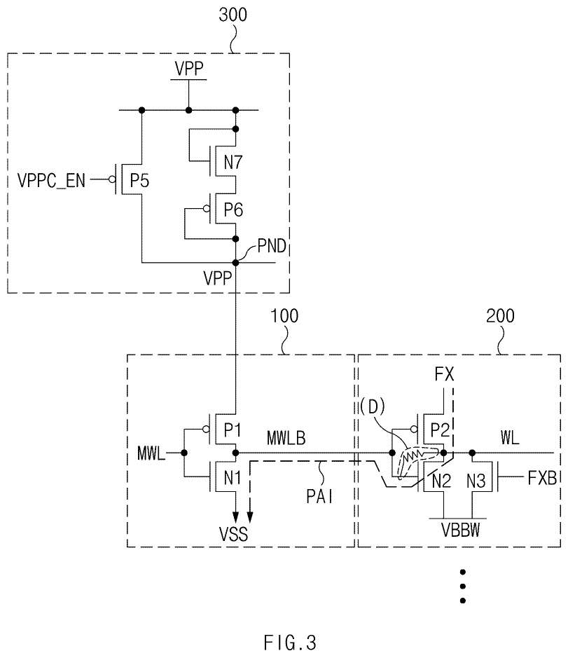

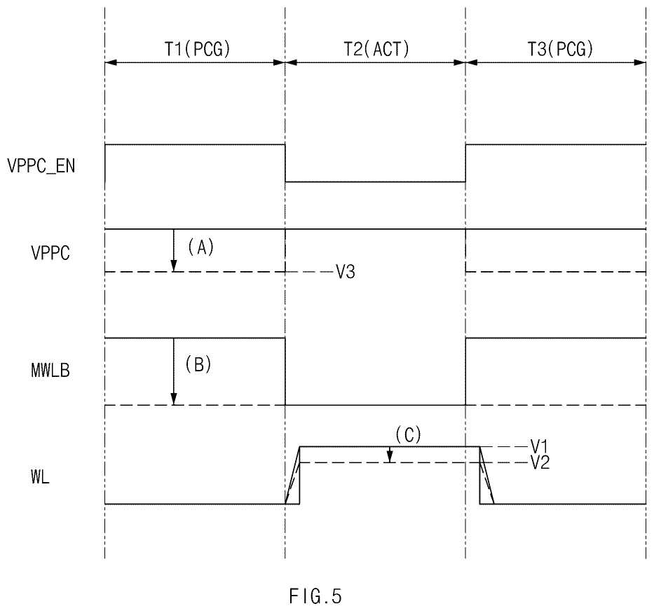

FIG. 3 is a circuit diagram illustrating voltage paths of the main wordline driver, the sub-wordline driver, and the source-voltage supply circuit shown in FIG. 1 during the active operation. FIG. 5 is a timing diagram illustrating operations of the semiconductor memory device shown in FIG. 1. The operations of FIG. 3 will be described with further reference to the timing diagram of FIG. 5.

Referring to FIG. 3, the semiconductor memory device such as a DRAM may perform the active operation in which the semiconductor memory device can access the memory cell MC to perform either the write operation to store data in the memory cell MC or the read operation to output data stored in the memory cell MC. The active operation may be performed by selecting and enabling one of the main wordline signals based on a row address, and selecting and enabling at least one of the wordlines WL assigned to the selected main wordline signal MWLB.

During the active operation, the active signal ACT may be activated. Accordingly, the driving voltage activation signal VPPC_EN may become a logic low level in the active operation period T2. As a result, the transistor P5 may be turned on, and the pumping voltage VPP may be applied to the power node PND. Here, since the gate terminal and the drain terminal of the transistors N7 and P6 are commonly connected to each other, the transistors N7 and P6 may maintain a turn-on state.

When the main wordline drive signal MWL is at a logic high level, the transistor P1 may be turned off and the transistor N1 may be turned on. Accordingly, the main wordline signal MWLB may transition to a logic low level.

When the main wordline signal MWLB transitions to a logic low level and the sub-wordline drive signal FX is at a logic high level, the transistor P2 may be turned on and the transistor N2 may be turned off, so that the wordline WL may transition to a logic high level. Since the sub-wordline drive signal FXB is an inversion signal of the sub-wordline drive signal FX, the sub-wordline drive signal FXB may be at a logic low level. Accordingly, the transistor N3 may maintain a turn-off state.

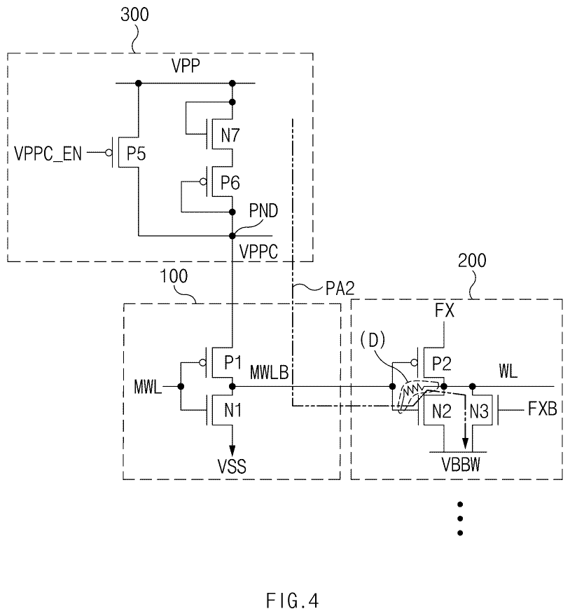

Here, when the main wordline signal MWLB is at a logic low level, the transistor N2 may maintain a turn-off state. However, as shown in D of FIG. 4, a short-circuit defect may occur between the gate terminal and the drain terminal of the transistor N2. In this case, even though the transistor N2 is turned off, a leakage current may occur in the transistor N2 along the path PA1. Accordingly, the voltage of the wordline WL may decrease from one voltage V1 to another voltage V2 by a voltage level C shown in FIG. 5.

As described above, when a short-circuit defect occurs in the transistor N2 of the sub-wordline driver 200 in the active operation period T2, the voltage level of the wordline WL may decrease, which may reduce the operating margin of the pumping voltage VPP. However, it may be difficult to independently confirm whether a short-circuit defect occurs in the transistor N2 of the sub-wordline driver 200. In particular, in a structure where the multiple wordlines WL share one main wordline signal MWLB, there is a limitation in repairing a defective wordline using a redundant address when the sub-wordline driver 200 is defective.

Accordingly, the semiconductor memory device may detect a level change of the driving voltage VPPC during the precharge operation period T1 or T3, so that the semiconductor memory device may independently screen whether a short-circuit defect occurs in the transistor N2 of the sub-wordline driver 200. The detailed operation for detecting such defects will be described later with reference to FIG. 4.

FIG. 4 is a circuit diagram illustrating voltage paths of the main wordline driver, the sub-wordline driver, the source-voltage supply circuit shown in FIG. 1 during the precharge operation period based on some embodiments of the present disclosure. The operations of FIG. 4 will be described with further reference to the timing diagram of FIG. 5.

Referring to FIG. 4, the precharge signal PCG may be activated during the precharge operation. Accordingly, the driving voltage activation signal VPPC_EN may become a logic high level during the precharge operation period (e.g., T1). As a result, the transistor P5 may be turned off, so that the driving voltage VPPC may be applied to the power node PND. Here, since the gate and drain terminals of the transistors N7 and P6 are commonly connected to each other, the transistors N7 and P6 may maintain a turn-on state.

When the transistor P5 is turned off, the voltage level of the driving voltage VPPC may be adjusted (i.e., clamped) so as not to fall below a voltage level calculated by subtracting, from the pumping voltage VPP, a threshold voltage corresponding to the sum of threshold voltages of the transistors N7 and P6.

When the main wordline drive signal MWL is at a logic low level, the transistor P1 may be turned on and the transistor N1 may be turned off. Accordingly, the main wordline signal MWLB may become a logic high level.

When the main wordline signal MWLB is at a logic high level and the sub-wordline drive signal FX is at a logic low level, the transistor N2 may be turned on and the transistor P2 may be turned off so that the wordline WL can transition to a logic low level. Since the sub-wordline drive signal FXB is an inversion signal of the sub-wordline drive signal FX, the sub-wordline drive signal FXB may be at a logic high level. Accordingly, the transistor N3 may be turned on so that the wordline WL may be pulled down to a negative wordline voltage VBBW level.

Here, when the main wordline signal MWLB is at a logic high level, the transistor N2 may be turned on. However, as shown in D of FIG. 4, a short circuit defect may occur between the gate terminal and the drain terminal of the transistor N2. In this case, a leakage current may occur in the transistor N2 along the path PA2 while the transistor N2 is turned on.

That is, charges of the main wordline signal MWLB flow out to the negative wordline voltage VBBW terminal of the transistor N2 through the source-voltage supply circuit 300 and the transistor P1. Accordingly, the driving voltage VPPC received from the power node PND may decrease by the voltage level A, so that the driving voltage VPPC may reach the voltage level V3. In addition, the voltage level of the main wordline signal MWLB may also decrease by the voltage level B.

As described above when a short-circuit defect occurs in the transistor N2 of the sub-wordline driver 200 during the active operation period T2, the voltage level of the wordline WL may decrease, which may reduce the operation margin of the pumping voltage VPP. However, it may be difficult to independently confirm whether a short-circuit defect occurs in the transistor N2 of the sub-wordline driver 200.

Therefore, the semiconductor memory device may determine whether a short-circuit defect occurs in the transistor N2 of the sub-wordline driver 200 by detecting whether the driving voltage VPPC decreases by the voltage level A in the precharge operation period T1 or T3.

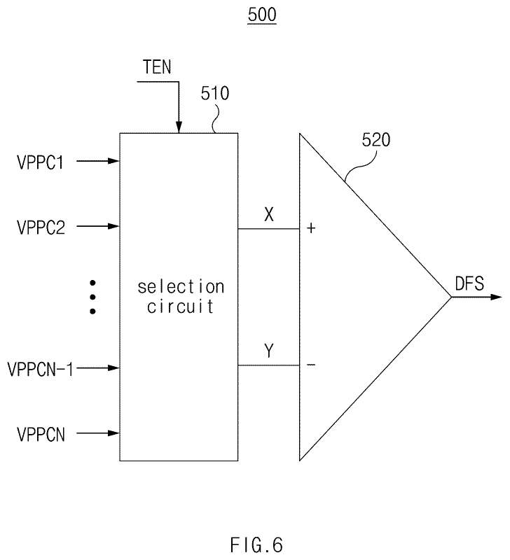

FIG. 6 is a circuit diagram illustrating the defect detection circuit shown in FIG. 1 based on some embodiments of the present disclosure.

Referring to FIG. 6, the defect detection circuit 500 may selectively compare the plurality of driving voltages VPPC1 to VPPCN with each other to generate a defect flag signal DFS indicating whether a defect exists. The defect detection circuit 500 may include a selection circuit 510 and a comparison circuit 520.

Here, the selection circuit 510 may multiplex a plurality of driving voltages VPPC1 to VPPCN supplied to the power node PND of the wordline driving circuits WLD1 and WLD2 based on the test enable signal TEN, and may output a first signal X and a second signal Y as the result of multiplexing. For example, the selection circuit 510 may select a pair of driving voltages from among the plurality of driving voltages VPPC1 to VPPCN, and may output the first signal X and the second signal Y as the result of selection.

In addition, the comparison circuit 520 may compare the first signal X with the second signal Y to generate a defect flag signal DFS.

For example, the comparison circuit 520 may compare the voltage levels of the first signal X and the second signal Y with each other, and may deactivate the defect flag signal DFS when the voltage levels of the first and second signals X and Y are equal to each other. That is, when the voltage levels of the first signal X and the second signal Y are equal to each other, this means that no voltage drop of the driving voltage VPPC has occurred and no defect has also occurred so that the defect flag signal DFS can be deactivated.

On the other hand, the comparison circuit 520 may compare the voltage levels of the first signal X with the second signal Y. When the two signals (i.e., the first and second signals X and Y) have different voltage levels, the defect flag signal DFS can be activated. That is, when the voltage levels of the first signal X and the second signal Y are different from each other, this means that the voltage drop of the driving voltage VPPC has occurred and the defect has also occurred, so that the defect flag signal DFS can be activated.

For example, the driving voltage VPPC1 from among the plurality of driving voltages VPPC1 to VPPCN may be a voltage that is matched to the wordline driving circuit WLD1 and the cell mat M1 illustrated in FIG. 1. In addition, the driving voltage VPPC2 from among the plurality of driving voltages VPPC1 to VPPCN may be a voltage that is matched to the wordline driving circuit WLD2 and the cell mat M2 illustrated in FIG. 1. Accordingly, the defect detection circuit 500 may detect whether there is a defect for each mat M1 and M2 by comparing the voltage levels of the driving voltages VPPC1 and VPPC2 corresponding to different mats M1 and M2.

FIG. 7 is a circuit diagram illustrating another embodiment of the defect detection circuit shown in FIG. 1 based on the present disclosure.

Referring to FIG. 7, the defect detection circuit 500_1 may detect the voltage level of the driving voltage VPPC based on the test enable signal TENB, and may generate the defect flag signal DFS indicating whether a defect occurs.

This defect detection circuit 500_1 may include an activation circuit 530 and a voltage level detection circuit 540.

Here, the activation circuit 530 may include a transistor P8. The transistor P8 may be a PMOS transistor. The transistor P8 may be connected between the pumping voltage VPP input terminal and the node ND1 so that the transistor P8 can receive the test enable signal TENB through a gate terminal thereof. Here, the test enable signal TENB may be an inversion signal of the test enable signal TEN.

The voltage level detection circuit 540 may include transistors P9 and N9. The transistor P9 may be a PMOS transistor, and the transistor N9 may be an NMOS transistor.

The transistors P9 and N9 may be connected in series between the node ND1 and the power-supply voltage VDD input terminal. Here, the power-supply voltage VDD may have a lower voltage level than the pumping voltage VPP. The transistors P9 and N9 may receive the driving voltage VPPC through a common gate terminal thereof. The transistors P9 and N9 may output the defect flag signal DFS through a common source terminal thereof.

For example, during the precharge operation period, the test enable signal TENB may be activated to a logic low level. Then, the transistor P8 may be turned on so that the pumping voltage VPP may be supplied to the node ND1. In addition, the voltage level detection circuit 540 may output the defect flag signal DFS in response to the voltage level of the driving voltage VPPC.

For example, when the voltage level of the driving voltage VPPC is higher than a preset reference voltage, the transistor N9 may be turned on and the transistor P9 may be turned off. Here, the reference voltage may be set to a threshold voltage level at which the transistor N9 is turned on.

Accordingly, the defect flag signal DFS may be output at the power-supply voltage VDD level. That is, when the defect flag signal DFS is output at the power-supply voltage VDD level, the driving voltage VPPC is output at a normal level without a voltage drop, which may indicate an example case where no defect has occurred.

On the other hand, when the voltage level of the driving voltage VPPC is lower than the preset reference voltage, the transistor N9 may be turned off and the transistor P9 may be turned on. Here, the reference voltage may be set to a threshold voltage level at which the transistor P9 is turned on.

Therefore, the defect flag signal DFS may be output at the pumping voltage VPP level according to the pumping voltage VPP supplied to the node ND1.

That is, when the defect flag signal DFS is output at the pumping voltage VPP level, the driving voltage VPPC is output at an abnormal level due to occurrence of a voltage drop, which may indicate an example case where a defect has occurred.

FIG. 8 is a block diagram illustrating a memory system 1 including the semiconductor memory device shown in FIG. 1 based on some embodiments of the present disclosure.

Referring to FIG. 8, the memory system 1 may include a semiconductor memory device 10 and a memory controller 20.

The memory system 1 may be implemented as an internal memory embedded in an electronic system (e.g., a smartphone, a tablet, a computer, a TV, etc.). For example, the memory system 1 may be a universal flash storage (UFS), an embedded multimedia card (eMMC), or a solid state drive (SSD).

According to an embodiment, the memory system 1 may be implemented as an external memory detachably coupled to an electronic device, and may be, for example, a UFS memory card, a compact flash (CF) card, a secure digital (SD) card, a micro Secure Digital (micro-SD) card, a mini Secure Digital (mini-SD) card, an eXtreme Digital (xD) card, or a memory stick.

The memory system 1 may store data received from the host in the semiconductor memory device 10 based on an access request from a host, or may read data requested by the host from the semiconductor memory device 10 and transmit the read data to the host.

The semiconductor memory device 10 may include a plurality of memory cells, each of which stores data. The semiconductor memory device 10 may correspond to the semiconductor memory device 10 shown in FIGS. 1 to 7. The semiconductor memory device 10 may transmit the defect flag signal DFS detected by the defect detection circuit 500 to the memory controller 20.

The memory controller 20 may provide a control signal CTRL, a command CMD, and an address ADDR to the semiconductor memory device 10. The control signal CTRL may include information necessary for the semiconductor memory device 10 to perform an operation corresponding to the command CMD received from the memory controller 20. For example, the control signal CTRL may include information about the sensing parameters necessary for the memory device 10 to read data from memory cells.

The command CMD may indicate an operation to be performed by the semiconductor memory device 10 during the active operation such as a write or read operation or during the precharge operation.

The address ADDR may indicate a position at which the memory controller 20 desires to access data in the semiconductor memory device 10. Data DATA may be transmitted and/or received between the memory controller 20 and the semiconductor memory device 10 based on the command CMD and the address ADDR.

The memory controller 20 may control various operations of the semiconductor memory device 10 in response to an access request from the host, for example, the write operation for writing data in the semiconductor memory device 10, the read operation for reading data from the semiconductor memory device 10, and/or the precharge operation for precharging data of the semiconductor memory device 10. For example, the memory controller 20 may transmit data DATA received from the host to the semiconductor memory device 10 by executing a write command, or may transmit data read from the semiconductor memory device 10 to the host by executing a read command. In addition, the memory controller 20 may provide a clock signal, a chip selection signal, etc. to the semiconductor memory device 10.

In addition, the memory controller 20 may receive the defect flag signal DFS from the semiconductor memory device 10 to determine whether a short-circuit defect has occurred in the wordline driving circuit WLD of the semiconductor memory device 10. The memory controller 20 may receive and store the defect flag signal DFS from the semiconductor memory device 10.

The semiconductor memory device according to the embodiments of the present disclosure may determine the presence or absence of a defect for each mat, so that the semiconductor memory device can reduce the area of a defect detection circuit and also reduce a test time required for determining the presence or absence of the defect.

The embodiments of the present disclosure may provide a variety of advantageous effects capable of being directly or indirectly recognized.

Although a number of illustrative embodiments of the present disclosure have been described, it should be understood that modifications and enhancements to the disclosed embodiments and other embodiments can be devised based on what is described and/or illustrated in the present disclosure. Furthermore, the embodiments may be combined to form additional embodiments.

What is claimed is:

1. A semiconductor memory device comprising:
at least one cell region including a plurality of memory cells connected between a plurality of wordlines and a plurality of bitlines, wherein a precharge operation is performed on the plurality of memory cells during a precharge operation period;
at least one source-voltage supply circuit configured to supply a second voltage having a lower level than a first voltage according to a second voltage activation signal;
at least one wordline driving circuit configured to operate based on the second voltage, and drive the plurality of wordlines according to a main wordline driving signal; and
a defect detection circuit configured to detect a level change of the second voltage during the precharge operation period, and output a defect flag signal indicating whether the at least one wordline driving circuit is defective.

2. The semiconductor memory device according to claim 1, wherein each of the at least one wordline driving circuit includes:
a main wordline driver configured to receive the second voltage as a source voltage, and generate a main wordline signal according to the main wordline driving signal; and
a plurality of sub-wordline drivers configured to drive the plurality of wordlines according to the main wordline signal and a sub-wordline driving signal.

3. The semiconductor memory device according to claim 2,
wherein the main wordline driver includes a first transistor and a second transistor connected in series between a power node to which the second voltage is applied and a ground voltage input terminal, and configured to receive the main wordline driving signal through a common gate terminal thereof and output the main wordline signal through a common drain terminal thereof.

4. The semiconductor memory device according to claim 2, wherein each of the plurality of sub-wordline drivers includes:
a third transistor and a fourth transistor connected in series between an input terminal of the sub-wordline drive signal and an input terminal of a negative wordline voltage, connected to a wordline through a common drain terminal thereof, and configured to receive the main wordline signal through a common gate terminal thereof.

5. The semiconductor memory device according to claim 4, wherein each of the plurality of sub-wordline drivers further includes a fifth transistor connected between the wordline and the input terminal of the negative wordline voltage, and configured to receive an inversion signal of the sub-wordline driving signal through a gate terminal thereof.

6. The semiconductor memory device according to claim 1,
wherein each of the at least one source-voltage supply circuit includes:
a sixth transistor connected between an input terminal of the first voltage and a power node and configured to be controlled according to the second voltage activation signal; and
a seventh transistor and an eighth transistor connected in series between the input terminal of the first voltage and the power node, the seventh transistor including a gate terminal and a drain terminal that are commonly connected to the input terminal of the first voltage, the eighth transistor including a gate terminal and a drain terminal that are commonly connected to the power node.

7. The semiconductor memory device according to claim 6,
wherein, when the second voltage activation signal is deactivated in an active operation period, the sixth transistor, the seventh transistor, and the eighth transistor are configured to be turned on to apply the first voltage to the power node, and
wherein, when the second voltage activation signal is activated in the precharge operation period, the sixth transistor is configured to be turned off and the seventh transistor and the eighth transistor are configured to be turned on to apply the second voltage to the power node.

8. The semiconductor memory device according to claim 7, wherein the second voltage has a voltage level obtained by subtracting a voltage level corresponding to a sum of threshold voltages of the seventh transistor and the eighth transistor from the first voltage.

9. The semiconductor memory device according to claim 1, wherein a number of the at least one source-voltage supply circuit corresponds to a number of the at least one cell region.

10. The semiconductor memory device according to claim 1, wherein the defect detection circuit is configured to be shared by the at least one wordline driving circuit, and detect levels of a plurality of second voltages supplied to the at least one wordline driving circuit.

11. The semiconductor memory device according to claim 1, wherein the defect detection circuit includes:
a selection circuit configured to multiplex a plurality of second voltages supplied to power nodes of different wordline driving circuits of the at least one wordline driving circuit according to a test enable signal, and output a result of multiplexing as a first signal and a second signal; and
a comparison circuit configured to compare the first signal with the second signal to generate the defect flag signal.

12. The semiconductor memory device according to claim 11, wherein the test enable signal is configured to be activated when a precharge signal for controlling the precharge operation is activated in the precharge operation period.

13. The semiconductor memory device according to claim 11, wherein the comparison circuit is configured to:
compare a voltage level of the first signal with a voltage level of the second signal; and
deactivate the defect flag signal when the voltage level of the first signal is equal to the voltage level of the second signal.

14. The semiconductor memory device according to claim 11, wherein the comparison circuit is configured to:
compare a voltage level of the first signal with a voltage level of the second signal; and
activate the defect flag signal when the voltage level of the first signal is different from the voltage level of the second signal.

15. The semiconductor memory device according to claim 1, wherein the defect detection circuit includes:
an activation circuit configured to selectively supply the first voltage to the first node according to a test enable signal; and
a voltage level detection circuit configured to output the defect flag signal at one level of a level of the first voltage and a level of a power-supply voltage based on a level of the second voltage.

16. The semiconductor memory device according to claim 15, wherein the activation circuit is configured to supply the first voltage to the first node when the test enable signal is activated in the precharge operation period.

17. The semiconductor memory device according to claim 15, wherein the activation circuit includes a ninth transistor connected between the first node and an input terminal of the first voltage, and configured to receive an inversion signal of the test enable signal through a gate terminal thereof.

18. The semiconductor memory device according to claim 15, wherein, when a level of the second voltage is equal to or higher than a preset reference voltage, the defect flag signal is output at the level of the power-supply voltage, and
wherein, when a level of the second voltage is lower than a level of the reference voltage, the defect flag signal is output at the level of the first voltage.

19. The semiconductor memory device according to claim 15, wherein the voltage level detection circuit includes a tenth transistor and an eleventh transistor connected in series between the first node and an input terminal of the power-supply voltage, and configured to receive the second voltage through a common gate terminal thereof and output the defect flag signal through a common source terminal thereof.

20. The semiconductor memory device according to claim 15, further comprising:
a driving signal generation circuit configured to receive an active signal for controlling an active operation of the at least one cell region and a precharge signal for controlling the precharge operation, and generate the main wordline driving signal, a sub-wordline driving signal, and the second voltage activation signal.
